(19) United States
(12) Patent Application Publication
(10) Pub. No.: US 2006/0055018 A1
(43) Pub. Date: Mar. 16, 2006

(54) Semiconductor device

(76) Inventors: Masahiro Sekiguchi, Yokohama-shi (JP); Chiaki Takubo, Tokyo (JP); Shuzo Akejima, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/224,056

(22) Filed: Sep. 13, 2005

(30) Foreign Application Priority Data
Sep. 14, 2004 (JP) P2004-266288

(51) Int. Cl. H01L 23/02

(52) U.S. Cl. 257/686

(57) ABSTRACT

A plurality of signal processing semiconductor elements are stacked on or above a circuit board. A rewiring silicon chip is mounted on or above the circuit board. The rewiring silicon chip has an inner conductor layer for connection between the plural signal processing semiconductor elements and between the circuit board and the signal processing semiconductor elements. The circuit board and the plural signal processing semiconductor elements are electrically connected, and the plural signal processing semiconductor elements are electrically connected to each other. The interconnection of the plural signal processing semiconductor elements and the rearrangement of electrode pads of the signal processing semiconductor elements are realized by the rewiring silicon chip.

### CROSS-REFERENCE TO THE INVENTION

This application is based upon and claims the benefit of priority from the prior Japanese Patent Application No. 2004-266288, filed on Sep. 14, 2004; the entire contents of which are incorporated herein by reference.

### BACKGROUND

1. Field of the Invention

The present invention relates to a semiconductor device in which a plurality of stacked semiconductor elements are mounted.

2. Description of the Related Art

In recent years, in order to realize the miniaturization, higher density packaging, and the like, a stacked multichip package in which a plurality of semiconductor elements (semiconductor chips) are stacked and sealed in one package has been in practical use. In the stacked multichip package, electrode pads of the plural semiconductor elements and electrode parts of a substrate are electrically connected by wire bonding or flipchip connection. For interconnection of the plural semiconductor elements, the electrode pads of the semiconductor elements are electrically connected to one another by wire bonding or the like.

In many cases, the arrangement pattern of the electrode pads of the plural semiconductor elements mounted on the substrate is not designed in consideration of the stacked package. Further, when general-purpose semiconductor elements are used, each semiconductor element sometimes has a different arrangement pattern of the electrode pads. Under such circumstances, the connection between the plural semiconductor elements or between the plural semiconductor elements and the substrate by wire bonding often results in a three-dimensional cross wiring. The three-dimensional cross wiring is a factor to cause a failure due to the complicated wiring structure and the contact between wires.

In some case, the plural semiconductor elements are interconnected by a wiring layer of the substrate side, and in this case, the substrate is loaded with wirings between the plural semiconductor elements in addition to the wirings to external connection terminals. This poses a problem that a substrate requires more advanced fine-pitch wiring technology and multilayer technology, which causes an increase in manufacturing cost of the substrate. This will be a factor to cause an increase in manufacturing cost of the multichip package. Further, the routing using the wiring layer of the substrate side has a limit in coping with different arrangement patterns of the pads of the plural semiconductor elements.

Also well known in the stacked multichip package is to dispose a circuit board between the plural semiconductor elements (see, for example, Japanese Patent Laid-open Application No. 2001-007278 and Japanese Patent Laid-open Application No. 2001-177050). This reduces the length of bonding wires connecting electrode pads of the semiconductor elements and electrode parts of the circuit board, and prevents the bonding wires from intersecting each other. However, the circuit board with a surface wiring structure has a limit in routing the wirings. Further, a circuit board with a multilayer wiring structure requires a high manufacturing cost, which leads to an increase in the total cost of the circuit board including an intermediate substrate. This will be a factor to increase the manufacturing cost of the stacked multichip package. Moreover, there is another problem that the thickness of the stacked package tends to increase.

### SUMMARY

A semiconductor device according to one embodiment of the present invention comprises a substrate, a plurality of signal processing semiconductor elements stacked on or above the substrate, a rewiring silicon chip which is disposed on or above the substrate and which has an inner conductor layer for at least one of electrical connection between the substrate and the signal processing semiconductor elements and electrical connection between the plural signal processing semiconductor elements, and a connecting part which has wirings electrically connecting the substrate and the plural signal processing semiconductor elements, at least part of the wirings including the inner conductor layer of the rewiring silicon chip.

A semiconductor device according to another embodiment of the present invention comprises a substrate, a plurality of signal processing semiconductor elements stacked on or above the substrate, a rewiring silicon chip which is disposed on or above the substrate and which has a conductor layer for at least one of electrical connection between the substrate and the signal processing semiconductor elements and electrical connection between the plural signal processing semiconductor elements, a first connecting part which has first wirings electrically connecting the substrate and the plural signal processing semiconductor elements, and a second connecting part which has second wirings electrically connecting the plural signal processing semiconductor elements to each other, at least part of the second wirings including the inner conductor layer of the rewiring silicon chip.

### BRIEF DESCRIPTION OF THE DRAWINGS

FIG. 1 is a view showing a rough structure of a semiconductor device according to a first embodiment of the present invention.

FIG. 2 is a perspective view showing a rewiring structure of the semiconductor device shown in FIG. 1.

FIG. 3 is a view showing a rough structure of a semiconductor device according to a second embodiment of the present invention.

FIG. 4 is a view showing a modification example of the semiconductor device shown in FIG. 2.

FIG. 5 is a view showing a rough structure of a semiconductor device according to a third embodiment of the present invention.

FIG. 6 is a view showing a modification example of the semiconductor device shown in FIG. 5.

FIG. 7 is a view showing another modification example of the semiconductor device shown in FIG. 5.

FIG. 8 is a view showing a rough structure of a semiconductor device according to a fourth embodiment of the present invention.

FIG. 9 is a view showing a rough structure of a semiconductor device according to a fifth embodiment of the present invention.

FIG. 10 is a view showing a modification example of the semiconductor device shown in FIG. 9.

FIG. 11 is a view showing another modification example of the semiconductor device shown in FIG. 9.

FIG. 12 is a view showing still another modification example of the semiconductor device shown in FIG. 9.

### DETAILED DESCRIPTION

Hereinafter, embodiments of the present invention will be described with reference to the drawings. Though the embodiments of the present invention will be described below based on the drawings, these drawings are provided only for an illustrative purpose and in no way are intended to limit the present invention.

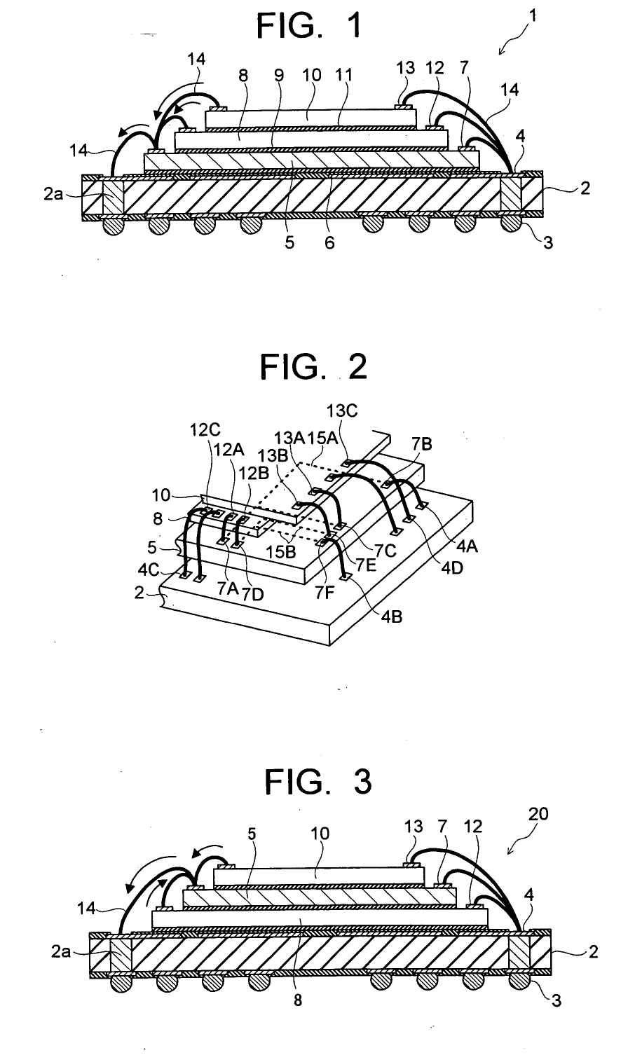

FIG. 1 is a view showing a rough structure of a semiconductor device according to a first embodiment of the present invention. A semiconductor device (semiconductor package) 1 with a stacked multichip structure shown in FIG. 1 has a circuit board 2 as an element mounting board. The circuit board 2 has a conductor layer formed on a surface or inside its insulating substrate. As the insulating substrate constituting the circuit board 2, usable are substrates of various kinds of insulative materials such as a resin substrate, a ceramic substrate, and a glass substrate. As the circuit board 2 using the resin substrate, a multilayer copper-clad laminate (multilayer printed wiring board) or the like is used.

On a lower surface of the circuit board 2, external connection terminals 3 made of metal bumps or the like, typically, solder bumps, are formed. On an upper surface of the circuit board 2, provided are electrode parts 4 electrically connected to the external connection terminals 3 via inner layer circuits 2a. On the upper surface being an element mounting surface of the circuit board 2, a rewiring silicon chip (rewiring silicon interposer) 5 is mounted. The rewiring silicon chip 5 is fixedly bonded on the circuit board 2 via a first bonding layer 6.

A fine-pitch wiring technology of a semiconductor is utilized in fabricating the rewiring silicon chip 5. The rewiring silicon chip 5 has an inner conductor layer and connection pads 7 connected thereto, the inner conductor layer constitutes fine-pitch wirings of similar to that in a typical semiconductor element. The rewiring silicon chip (rewiring semiconductor element) 5 is intended dedicatedly for realizing the interconnection of the plural signal processing semiconductor elements and the rearrangement of electrode pads of the signal processing semiconductor elements, and is different from the signal processing semiconductor elements functioning as a computing element, a storage element, a control element, and so on. Therefore, the rewiring silicon chip 5 is a semiconductor element dedicated for rewiring, which only has a conductor layer (wiring) and does not have a signal processing part such as a computing part or a storage part.

On the rewiring silicon chip 5, a first signal processing semiconductor element (first signal processing silicon chip) 8 is stacked. The first signal processing semiconductor element 8 is fixedly bonded on the rewiring silicon chip 5 via a second bonding layer 9. Further, on the first signal processing semiconductor element 8, a second signal processing semiconductor element (second signal processing silicon chip) 10 is stacked. The second signal processing semiconductor element 10 is fixedly bonded on the first signal processing semiconductor element 8 via a third bonding layer 11. As the first and second signal processing semiconductor elements 8, 10, semiconductor elements each having a signal processing part constituted of a semiconductor circuit such as a computing element, a storage element, or a control element are used.

The first and second signal processing semiconductor elements 8, 10 and the circuit board 2 are electrically connected to each other. Wirings connecting them constitute a first connecting part. The first connecting part has, as at least part thereof, wirings including the inner conductor layer of the rewiring silicon chip 5. Specifically, the first and second signal processing semiconductor elements 8, 10 have electrode pads 12, 13 respectively. At least part of these electrodes pads 12, 13 are electrically connected to connection pads 7 of the rewiring silicon chip 5 via bonding wires 14. The connection pads 7 of the rewiring silicon chip 5 are further electrically connected to electrode parts 4 of the circuit board 2 via bonding wires 14. Part of the electrode pads 12, 13 of the first and second signal processing semiconductor elements 8, 10 may be connected directly to the circuit board 2.

Further, a second connecting part connecting the first signal processing semiconductor element 8 and the second signal processing semiconductor element 10 to each other has, as at least part thereof, wirings including the inner conductor layer of the rewiring silicon chip 5. At least part of electrode pads 12, 13 connecting the first and second signal processing semiconductor elements 8, 10 to each other are electrically connected to connection pads 7 of the rewiring silicon chip 5 via bonding wires 14 respectively. The first and second signal processing semiconductor elements 8, 10 are electrically connected to each other via the rewiring silicon chip 5. Incidentally, part of the electrode pads 12, 13 of the first and second signal processing semiconductor elements 8, 10 may be connected directly to each other, depending on their positions.

A connection using the bonding wires 14 is employed for the electrical connection between the first and second signal processing semiconductor elements 8, 10 and the rewiring silicon chip 5, between the rewiring silicon chip 5 and the circuit board 2, and between the first and second signal processing semiconductor elements 8, 10 and the circuit board 2. FIG. 2 shows an example of such a wiring structure. The rewiring structure using the rewiring silicon chip 5 will be described with reference to FIG. 2.

In the rewiring structure shown in FIG. 2, an electrode pad 12A of the first signal processing semiconductor element 8 is connected to a connection pad 7A of the rewiring silicon chip 5. The connection pad 7A is connected to one end of an internal wiring 15A, and the other end of the internal wiring 15A is connected to a connection pad 7B. The electrode pad 12A of the first signal processing semiconductor element 8 is rearranged by the connection pad 7B of the rewiring silicon chip 5, and the connection pad 7B is connected to an electrode part 4A of the circuit board 2. The internal wiring 15A also has a function of interconnecting the first and second signal processing semiconductor elements 8, 10. A connection pad 7C connected to a branch line of the internal wiring 15A is connected to an electrode pad 13A of the second signal processing semiconductor element 10.

An electrode pad 12B of the first signal processing semiconductor element 8 and an electrode pad 13B of the second signal processing semiconductor element 10 are connected to each other via an internal wiring 15B of the rewiring silicon chip 5. The electrode pad 12B is connected to a connection pad 7D of the rewiring silicon chip 5, and the electrode pad 13B is connected to a connection pad 7E of the rewiring silicon chip 5. The connection pads 7D, 7E are provided on both ends of the internal wiring 15B respectively. The internal wiring 15B connecting the electrode pads 12B, 13B to each other is further connected to an electrode part 4B of the circuit board 2 via a connection pad 7F.

An electrode pad 12C of the first signal processing semiconductor element 8 and an electrode pad 13C of the second signal processing semiconductor element 10 which do not require rewiring are directly connected to electrode parts 4C, 4D of the circuit board 2 respectively. The electrode pads 12C, 13C not requiring the rewiring can be thus directly connected to the circuit board 2 by wire bonding. The electrical connection between the pads 7 of the rewiring silicon chip 5 and the electrode pads 12, 13 of the signal processing semiconductor elements 8, 10 and the electrical connection between the pads 7 of the rewiring silicon chip 5 and the electrode parts 4 of the circuit board 2 are realized by the bonding wires 14. The same connection structure is employed for the direct connection between the electrode pads 12C, 13C of the signal processing semiconductor elements 8, 10 and the electrode parts 4C, 4D of the circuit board 2.

The first and second signal processing semiconductor elements 8, 10 together with the rewiring silicon chip 5 and the bonding wires 14 are sealed with sealing resin (not shown). In this manner, the semiconductor device 1 with the stacked multichip package structure is configured. Incidentally, the semiconductor device 1 shown in FIG. 1 has the two signal processing semiconductor elements 8, 10 mounted on the circuit board 2, but the number of the mounted signal processing semiconductor elements is not limited to two, but may be three or more. This also applies to other embodiments to be described later.

In the semiconductor device 1 with the stacked multichip package structure, the use of the rewiring silicon chip 5 realizes the interconnection of the plural signal processing semiconductor elements 8, 10 and the rearrangement of the electrode pads 12, 13 of the signal processing semiconductor elements 8, 10. This makes it possible to prevent the wiring structure from becoming complicated and a failure from occurring due to the complication. Further, since the rewiring silicon chip 5 utilizes the fine-pitch wiring technology of a semiconductor, it is possible not only to reduce its own manufacturing cost but also to reduce cost required for the circuit board 2. For example, by routing signal lines in the rewiring silicon chip 5 that can employ the fine-pitch wiring, the circuit board 2 is loaded only with wirings up to the external connection terminals 3. Because of these reasons, it is possible to reduce manufacturing cost of the semiconductor device 1 with the stacked multichip package structure including the rewiring silicon chip 5.

Further, in the rewiring silicon chip 5, the fine-pitch wiring is realized with a thickness equivalent to that of a typical semiconductor element. Therefore, the thickness of the semiconductor device 1 with the stacked multichip package structure does not increase. Moreover, since the rewiring silicon chip 5 is made of a material such as Si similarly to a typical semiconductor element, no thermal problem occurs even when it is stacked on the circuit board 2 together with the signal processing semiconductor elements 8, 10. Specifically, when a typical circuit board is disposed between a plurality of semiconductor elements, heat application thereto tends to cause a warp or the like due to different thermal expansion coefficients of constituent materials thereof. On the other hand, the rewiring silicon chip 5 does not cause a warp or the like ascribable to different thermal expansion coefficients.

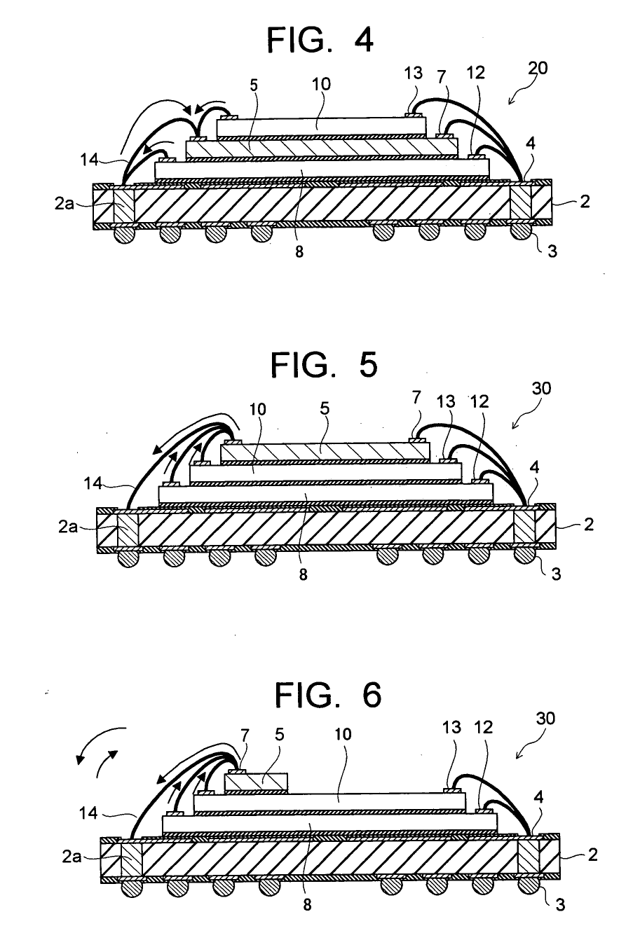

Next, semiconductor devices according to a second embodiment of the present invention will be described with reference to FIG. 3 and FIG. 4. FIG. 3 and FIG. 4 are views showing rough structures of the semiconductor devices according to the second embodiment. The same reference numerals are used to designate the same portions as those of the first embodiment, and description thereof will be partly omitted. In each of semiconductor devices (semiconductor packages) 20 shown in these drawings, a rewiring silicon chip 5 is stacked between a first signal processing semiconductor element 8 and a second signal processing semiconductor element 10. That is, the first signal processing semiconductor element 8 is fixedly bonded on an element mounting surface (upper surface) of a circuit board 2. On the first signal processing semiconductor element 8, the rewiring silicon chip 5 is fixedly bonded, and the second signal processing semiconductor element 10 is further fixedly bonded thereon.

Electrode pads 12, 13 of the first and second signal processing semiconductor elements 8, 10 are electrically connected to electrode parts 4 of the circuit board 2 directly or via the rewiring silicon chip 5. Further, the first and second signal processing semiconductor elements 8, 10 are electrically connected to each other directly or via the rewiring silicon chip 5. The connection between the signal processing semiconductor elements 8, 10 and the rewiring silicon chip 5, the connection between the rewiring silicon chip 5 and the circuit board 2, and the connection between the signal processing semiconductor elements 8, 10 and the circuit board 2 are realized by bonding wires 14. The interconnection of the first and second signal processing semiconductor elements 8, 10 and the rearrangement of the electrode pads 12, 13 of the signal processing semiconductor elements 8, 10 are realized by the rewiring silicon chip 5, as in the above-described first embodiment.

As described above, the rewiring silicon chip 5 may be disposed between the first signal processing semiconductor element 8 and the second signal processing semiconductor element 10. In this case, the connection to the rewiring silicon chip 5 can be realized by, for example, the direct connection of the bonding wires 14 to connection pads 7, for example, as shown in FIG. 3. Alternatively, as shown in FIG. 4, the electrode parts 4 of the circuit board 2 and the connection pads 7 of the rewiring silicon chip 5 may be connected by the bonding wires 14 after the bonding wires 14 are once connected to the electrode parts 4. The arrangement of the rewiring silicon chip 5 between the first signal processing semiconductor element 8 and the second signal processing semiconductor element 10 makes it possible to realize a wider variety of wiring structures.

Further, according to the semiconductor devices 20 of the second embodiment, without increasing manufacturing cost and thickness of the semiconductor device 20, it is possible to prevent the wiring structure from becoming complicated and a failure from occurring due to the complication, as in the first embodiment. Further, the problem of the warp in the stacked multichip package structure can be overcome. Because of these reasons, it is possible to provide at low cost the semiconductor device 20 with the stacked multichip package structure superior in versatility and reliability.

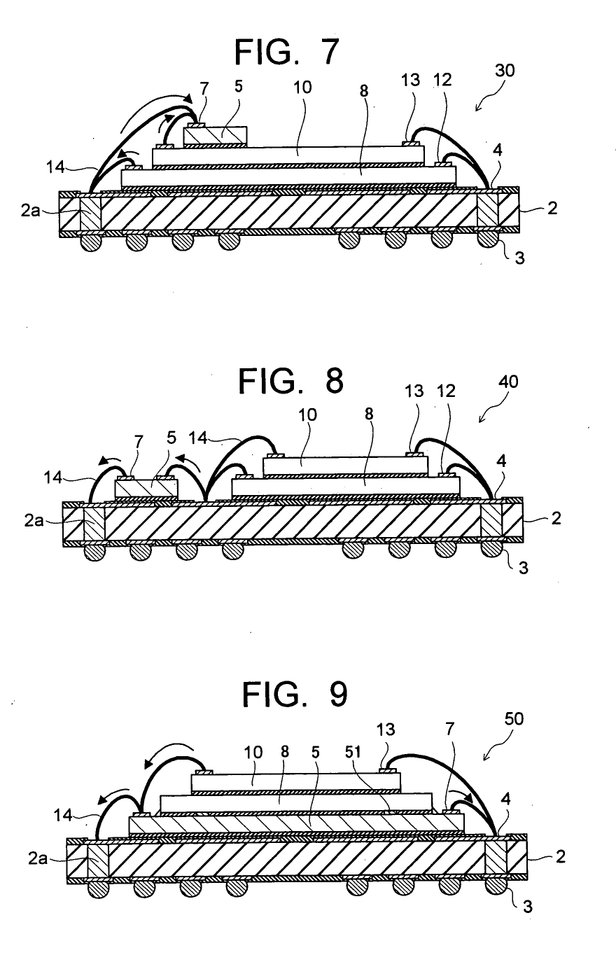

Next, semiconductor devices according to a third embodiment of the present invention will be described with reference to FIG. 5, FIG. 6, and FIG. 7. FIG. 5, FIG. 6, and FIG. 7 are views showing rough structures of the semiconductor devices according to the third embodiment. The same reference numerals are used to designate the same portions as those of the first and second embodiments, and description thereof will be partly omitted. In each of semiconductor devices (semiconductor packages) 30 shown in these drawings, a rewiring silicon chip 5 is disposed on an uppermost layer of stacked signal processing semiconductor elements 8, 10. Specifically, the first signal processing semiconductor element 8 is fixedly bonded on an element mounting surface (upper surface) of a circuit board 2, and the second signal processing semiconductor element 10 is fixedly bonded thereon. The rewiring silicon chip 5 is fixedly bonded on the second signal processing semiconductor element 10.

Electrode pads 12, 13 of the first and second signal processing semiconductor elements 8, 10 are electrically connected to electrode parts 4 of the circuit board 2 directly or via the rewiring silicon chip 5. Further, the first and second signal processing semiconductor elements 8, 10 are electrically connected to each other directly or via the rewiring silicon chip 5. The connection between the signal processing semiconductor elements 8, 10 and the rewiring silicon chip 5, the connection between the rewiring silicon chip 5 and the circuit board 2, and the connection between the signal processing semiconductor elements 8, 10 and the circuit board 2 are realized by bonding wires 14. The interconnection of the first and second signal processing semiconductor elements 8, 10 and the rearrangement of the electrode pads 12, 13 of the signal processing semiconductor elements 8, 10 are realized by the rewiring silicon chip 5, as in the above-described first embodiment.

As described above, the rewiring silicon chip 5 may be disposed on the uppermost layer of the stacked signal processing semiconductor elements 8, 10. In this case, if the number of pads of the signal processing semiconductor elements 8, 10 that require the rewiring is small, the rewiring silicon chip 5 may be reduced in size or may be disposed with offset, as shown in FIG. 6 and FIG. 7. The connection to the rewiring silicon chip 5 may be realized by the direct connection of the bonding wires 14 to connection pads 7 as shown in FIG. 6, or by connecting the bonding wires 14 to the connection pads 7 of the rewiring silicon chip 5 after once connecting the bonding wires 14 to the electrode parts 4 of the circuit board 2, as shown in FIG. 7.

Next, a semiconductor device according to a fourth embodiment of the present invention will be described with reference to FIG. 8. FIG. 8 is a view showing a rough structure of the semiconductor device according to the fourth embodiment. The same reference numerals are used to designate the same portions as those of the first to third embodiments, and description thereof will be partly omitted. In a semiconductor device (semiconductor package) 40 shown in FIG. 8, are wiring silicon chip 5 is fixedly bonded directly on an element mounting surface (upper surface) of a circuit board 2, separately from stacked signal processing semiconductor elements 8, 10. Both the rewiring silicon chip 5 and the signal processing semiconductor elements 8, 10 may be disposed on the circuit board 2, the rewiring silicon chip 5 not being stacked but disposed directly on the circuit board 2. Even with such a structure, the interconnection of the signal processing semiconductor elements 8, 10 and the rearrangement of electrode pads 12, 13 of the signal processing semiconductor elements 8, 10 can be realized by the rewiring silicon chip 5.

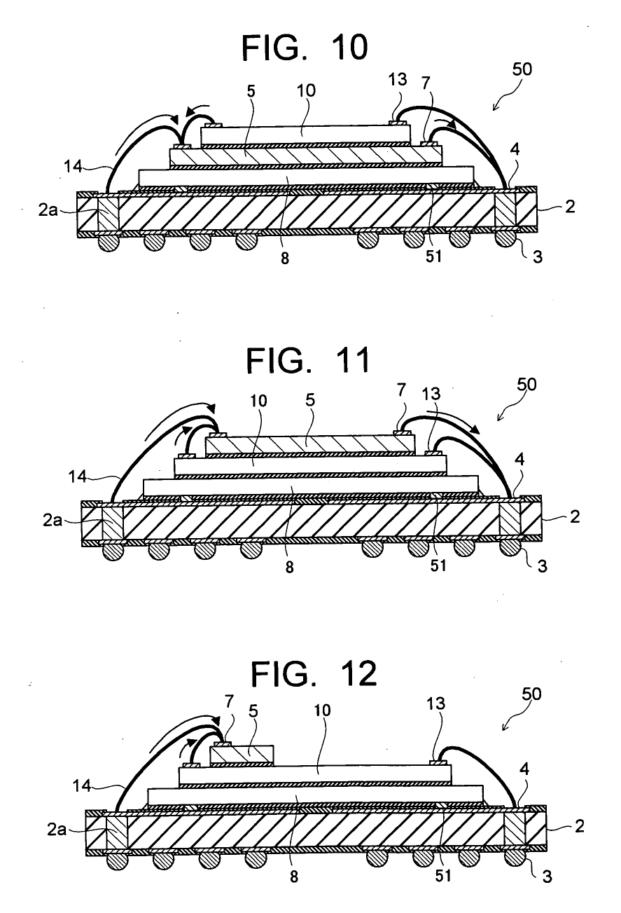

Next, semiconductor devices according to a fifth embodiment of the present invention will be described with reference to FIG. 9, FIG. 10, FIG. 11, and FIG. 12. These figures are views showing rough structures of the semiconductor devices according to the fifth embodiment. The same reference numerals are used to designate the same portions as those of the first to fourth embodiments, and description thereof will be partly omitted. In each of semiconductor devices (semiconductor packages) 50 shown in these drawings, flipchip connection, in addition to wire bonding connection, is employed for the connection between a circuit board 2 and signal processing semiconductor elements 8, 10, or between a rewiring silicon chip 5 and the signal processing semiconductor elements 8, 10. The interconnection of the signal processing semiconductor elements 8, 10 and the rearrangement of electrode pads 12, 13 of the signal processing semiconductor elements 8, 10 are realized by the rewiring silicon chip 5.

In the semiconductor device 50 shown in FIG. 9, the rewiring silicon chip 5 is fixedly bonded on the circuit board 2. The first signal processing semiconductor element 8 is disposed on and electrically and mechanically connected to the rewiring silicon chip 5 via metal bumps 51. The second signal processing semiconductor element 10 is fixedly bonded on the first signal processing semiconductor element 8. The first signal processing semiconductor element 8 and the rewiring silicon chip 5 are electrically connected via the metal bumps 51. The electrical connection between the rewiring silicon chip 5 and the circuit board 2 and the electrical connection between the rewiring silicon chip 5 and the second signal processing semiconductor element 10 are realized by bonding wires 14. Incidentally, it is also possible to flipchip-connect the rewiring silicon chip 5 to the circuit board 2.

In the semiconductor device 50 shown in FIG. 10, the first signal processing semiconductor element 8 is disposed on and electrically and mechanically connected to the circuit board 2 via metal bumps 51. The rewiring silicon chip 5 is fixedly bonded on the first signal processing semiconductor element 8, and the second signal processing semiconductor element 10 is further fixedly bonded thereon. The first signal processing semiconductor element 8 and the circuit board 2 are electrically connected via metal bumps 51. The electrical connection between the rewiring silicon chip 5 and the circuit board 2 and the electrical connection between the rewiring silicon chip 5 and the signal processing semiconductor elements 8, 10 are realized by bonding wires 14. The rewiring silicon chip 5 can be flipchip-connected to the first signal processing semiconductor element 8.

In each of the semiconductor devices 50 shown in FIG. 11 and FIG. 12, the first signal processing semiconductor element 8 is disposed on and electrically and mechanically connected to the circuit board 2 via metal bumps 51. The second signal processing semiconductor element 10 is fixedly bonded on the first signal processing semiconductor element 8, and the rewiring silicon chip 5 is further fixedly bonded thereon. The first signal processing semiconductor element 8 and the circuit board 2 are electrically connected via the metal bumps 51. The electrical connection between the rewiring silicon chip 5 and the circuit board 2 and the electrical connection between the rewiring silicon chip 5 and the signal processing semiconductor elements 8, 10 are realized by bonding wires 14. The rewiring silicon chip 5 can be also flipchip-connected to the second signal processing semiconductor element 10.

As described above, the flipchip connection may be employed for the connection between the circuit board 2 and the signal processing semiconductor elements 8, 10 and between the rewiring silicon chip 5 and the signal processing semiconductor elements 8, 10. According to such semiconductor devices 50 of the fifth embodiment, without increasing manufacturing cost, thickness, and so on of the semiconductor devices 50, it is possible to prevent the wiring structure from becoming complicated and a failure from occurring due to the complication, as in the first to fourth embodiments. In addition, the problem of the warp in the stacked multichip package structure can be overcome. Because of these reasons, it is possible to provide at low cost the semiconductor devices 50 with the stacked multichip package structure superior in versatility and reliability.

It should be noted that the present invention is not limited to the embodiments described above, but is applicable to various kinds of semiconductor devices in which a plurality of stacked semiconductor elements are mounted. Such semiconductor devices are considered as being embraced in the present invention. Various modifications can be made without departing from the spirit of the present invention when the present invention is embodied. Further, the present invention can be embodied by appropriately combining the embodiments to an allowable extent, which can provide combined effects. Further, the above-described embodiments include inventions on various stages, and by appropriately combining these inventions under a plurality of features that are disclosed, various inventions can be extracted therefrom.

What is claimed is:

1. A semiconductor device, comprising:
a substrate;
a plurality of signal processing semiconductor elements stacked on or above the substrate;
a rewiring silicon chip which is disposed on or above the substrate and which has an inner conductor layer for at least one of electrical connection between the substrate and the signal processing semiconductor elements and electrical connection between the plural signal processing semiconductor elements; and
a connecting part which has wirings electrically connecting the substrate and the plural signal processing semiconductor elements, at least part of the wirings including the inner conductor layer of the rewiring silicon chip.

2. The semiconductor device as set forth in claim 1,
wherein the rewiring silicon chip and the plural signal processing semiconductor elements are stacked together.

3. The semiconductor device as set forth in claim 2,
wherein the rewiring silicon chip is mounted on the substrate, and the plural signal processing semiconductor elements are stacked on the rewiring silicon chip.

4. The semiconductor device as set forth in claim 2,
wherein the rewiring silicon chip is stacked between the plural signal processing semiconductor elements or on the plural signal processing semiconductor elements.

5. The semiconductor device as set forth in claim 1,
wherein the rewiring silicon chip is mounted directly on the substrate, separately from the plural signal processing semiconductor elements.

6. The semiconductor device as set forth in claim 1,
wherein the connecting part has at least one connection mechanism selected from wire bonding connection and flipchip connection.

7. The semiconductor device as set forth in claim 1,
wherein the rewiring silicon chip has connection pads which rearrange electrode pads of the signal processing semiconductor elements by the inner conductor layer.

8. The semiconductor device as set forth in claim 7,
wherein the signal processing semiconductor elements are connected to the rewiring silicon chip by wire bonding connection or flipchip connection, and are connected to the substrate by wire bonding connection or flipchip connection via the connection pads which rearrange the electrode pads.

9. A semiconductor device, comprising:
a substrate;
a plurality of signal processing semiconductor elements stacked on or above the substrate;
a rewiring silicon chip which is disposed on or above the substrate and which has an inner conductor layer for at least one of electrical connection between the substrate and the signal processing semiconductor elements and electrical connection between the plural signal processing semiconductor elements;
a first connecting part which has first wirings electrically connecting the substrate and the plural signal processing semiconductor elements; and
a second connecting part which has second wirings electrically connecting the plural signal processing semiconductor elements to each other, at least part of the second wirings including the inner conductor layer of the rewiring silicon chip.

10. The semiconductor device as set forth in claim 9,
wherein at least part of the first wirings includes the inner conductor layer of the rewiring silicon chip.

11. The semiconductor device as set forth in claim 9,
wherein the rewiring silicon chip and the plural signal processing semiconductor elements are stacked together.

12. The semiconductor device as set forth in claim 11,
wherein the rewiring silicon chip is mounted on the substrate, and the plural signal processing semiconductor elements are stacked on the rewiring silicon chip.

13. The semiconductor device as set forth in claim 11,
wherein the rewiring silicon chip is stacked between the plural signal processing semiconductor elements or on the plural signal processing semiconductor elements.

14. The semiconductor device as set forth in claim 9,
wherein the rewiring silicon chip is mounted directly on the substrate, separately from the plural signal processing semiconductor elements.

15. The semiconductor device as set forth in claim 9,
wherein each of the first and second connecting parts has at least one connection mechanism selected from wire bonding connection and flipchip connection.

16. The semiconductor device as set forth in claim 9,
wherein the plural signal processing semiconductor elements are connected to the rewiring silicon chip by wire bonding connection or flipchip connection, and are connected to each other via the inner conductor layer of the rewiring silicon chip.

17. The semiconductor device as set forth in claim 10,
wherein the rewiring silicon chip has connection pads which rearrange electrode pads of the signal processing semiconductor elements by the inner conductor layer.

18. The semiconductor device as set forth in claim 17,
wherein the signal processing semiconductor elements are connected to the rewiring silicon chip by wire bonding connection or flipchip connection, and are connected to the substrate by wire bonding connection or flipchip connection via the connection pads which rearrange the electrode pads.
